(19) United States
(12) Patent Application Publication
(10) Pub. No.: US 2011/0237051 A1
(43) Pub. Date: Sep. 29, 2011

(54) PROCESS AND APPARATUS FOR DEPOSITION OF MULTICOMPONENT SEMICONDUCTOR LAYERS

(76) Inventors: Kenneth Lee Hess, Anaheim Hills, CA (US); Simon Charles Stewart Thomas, Cambridgeshire (GB); Johannes Kappeler, Wurselen (DE)

(21) Appl. No.: 12/748,368

(22) Filed: Mar. 26, 2010

(51) Int. Cl. H01L 21/205

(52) U.S. Cl. 438/478; 118/722; 118/723 R; 118/725; 257/E21.108

(57) ABSTRACT

A deposition process involves the formation of multicomponent semiconductor layers, in particular III-V epitaxial layers, on a substrate. Due to pyrolytic decomposition inside the reaction chamber, one of the process gases forms a first decomposition product. Together with a second decomposition product of a second process gas, the decomposition products form a layer on the surface of a heated substrate and also adhere to surfaces of the process chamber. To remove these adherences, during an etching step a purge gas containing a reactive substance formed by free radicals is introduced into the process chamber. The etching step may be performed before or after the deposition process.

The invention relates to a method and a device for depositing multicomponent semiconductor layers, in particular III-V epitaxial layers on at least one substrate.

US 2004/0033310 A1 discloses a method for depositing TiCl on a Al₂O₃ substrates. A process gas is introduced by means of an inlet member into a process chamber. In the process chamber is at least one substrate located. The substrate is carried by a susceptor. The susceptor is heated from below. The process gas decomposes pyrolitically inside of the heated process chamber. A layer is formed on the substrate and some material adheres to the process chamber surface. A reactive purge gas is emitted to the deposition chamber from purge gas inlets effective to form a reactive gas curtain over the chamber surface. With such reactive gas reacts the adhering to a volatile product to be removed from the process chamber.

US 2006/0121193 A1 discloses a process for producing semiconductor layers on a substrate carried by a substrate holder in a process chamber of a reactor. The layer consist of at least two material components, which are gallium and nitride. The source material for the gallium component is trimethylgallium TMGa. The nitrogen component is a decomposition product of ammonia. The device has a preconditioning apparatus to precondition the hydrides. Radicals are produced and injected directly into the diffusion boundary layer above the substrate to increase the growth rate of the layer.

U.S. Pat. No. 7,524,532 B2 discloses a device for growing thin films on a substrate in a process chamber wherein the process gases enter the process chamber through outlet openings of a shower head.

In a process chamber of an epitaxial reactor in which III-V layers are grown on a sapphire substrate, the metalorganic component decomposes not only on the substrate surface but also on several other surfaces of the process chamber. So coating of surfaces of the process chamber is not avoidable. Such adherences occur on the susceptor and on the ceiling of the process chamber, which is formed by a bottom plate of a shower head. Adduct generation occurs in the ceiling plate and the susceptor with satellites of different types of planetary reactors. Usually HCl or other reactive molecules are used together with a purge gas to clean the surfaces by an etching reaction. The metal-components are formed into a volatile halide. Using dry hydrochloric acid as a reactive molecule has disadvantages since this substance is very aggressive to metals.

The object of the invention is to provide a better cleaning method for a process chamber. A further object of the invention is to provide a method for cleaning a substrate prior to the deposition process. A further object of the invention is to provide a device for a growth process. A further object of the invention is to provide a method to etch masked layers. A further object of the invention is to provide an in-situ susceptor/wafer carrier cleaning. A further object of the invention is to provide an ex-situ reactor component cleaning. A further object of the invention is to provide a method for cleaning an MOCVD reactor component after manufacturing.

The object is achieved by the invention given in the claims.

According to the invention, the reactive substance is a free radical. These free radicals can be molecules. Preferably, the radicals are alkyl radicals like methyl radicals and ethyl radicals. They are formed by treating a precursor with energy. Precursors are preferably azomethane, acetone, 2,3-butanedione. Precursors used for free radical generation are organic compound containing alkyl groups. Examples of useful organic compounds are as follows:
1. Aldehydes—RCHO
2. Ketones—RCOR
   includes the special ketone compound dimethylketene —(CH₃)₂C═C═O
3. Organcic Acids—RCOOH
4. Organic Esters—RCOOR
5. Acid Anhydrides—R2CO—O—CO—R
6. Alcohols—ROH
7. Esters—ROR
8. Peroxides—R—O—O—R
9. Amines—RN₂, R2NH, R3n (primary, secondary, tertiary)
10. Amines—RCONH₂
11. Azo Compounds—R—N═N—R
12. Diazo Compounds—R2C═N═N (zwitter ion)
13. Azides R—N═N═N
14. Alkyl Nitroso Compounds—R—N═O
15. Nitro Compound—R—NO₂
16. Organic Nitrites—R—O—NO
17. Organic Nitrates—R—O—NO₂
18. Organic Nitriles R—CN
19. Miscellaneous Mitrogen Containing Organic Compounds—methylisocyanate CH₃—NCO
20. Alkyl Halides—RX, X=halogen atom
21. Organic hypochlorites R—OCI

Where R represents an alkyl group and molecules with more than one alkyl group have different R group compositions.

Additionally other hydrocarbon compounds could be used (paraffins, olefinic, acetylenic) as well as other alkylated precursors.

These organic precursors can be exposed by UV light to photofragmentize the precursors into methyl radicals, wherein nitrogen or carbon monoxide are byproducts, which do not interact with the substances used for etching the layers.

The device comprises a purge gas generator, which has a reaction chamber and a device supplying energy to a precursor. The energy can be provided by a plasma generator, by a heater or preferably by a UV light source. This light emits the dissociation energy to the precursor to create the free radicals. The free radicals are transported by a carrier gas from the purge gas generator to the process chamber. They enter the process chamber via the gas inlet member or via a separate gas inlet device. The free radicals react with the adhered III-metal and form a volatile reaction product in particular TMGa, which can be recycled to a source material to form a process gas after being cleaned and conditioned. Additionally different metalorganic components are be re-cycled for example TMIn, TMAl and the TE(x) equivalents. Carbon deposits on the reactor surfaces can be removed with the method.

The forementioned etching step can take place prior to or after a deposition step. If the etching step takes place after a deposition step, the substrates are removed out of the process chamber prior to the etching step. If the etching step takes place prior to the deposition step, substrates, which are not affected by the free radicals, may be inside the process chamber. Preferably sapphire substrates are inside the process chamber during the etching step. Unwanted metallic contaminations on the substrate surface are removed by the free radicals. Not only sapphire can be used as substrates. Other substrate types including silicon, SiC, ZnO, InP or GaAs may be used as well.

Free radicals may be used to remove defined areas of a layer from a coated substrate. The substrate is coated with a layer, in particular a III-V layer by an MOCVD-process using a metalorganic component and a hydride in an epitaxial reactor. The layer is covered by a mask, which has a material, which is not affected by the free radicals. The masked layer is exposed to a gas flow containing free radicals. The free radicals react with the III-component and/or the V-component and remove the layer from the substrate in the unmasked (exposed) areas. This is an isotropic etching process. If the V-component is N, volatile N₂ or more likely (CH₃)₃N is produced.

Reactor components may be cleaned by etching them in a reaction chamber of a reactor housing. Deposits on the surface of manufactured components can be removed prior to the first use of the component in a reactor.

### BRIEF DESCRIPTION OF THE DRAWINGS

Preferred embodiments of the invention are described below with reference to the following accompanying drawings:

FIG. 1 is a diagrammatic sectional view of a chemical vapor deposition apparatus usable in accordance with an aspect of the invention;

FIG. 2 is a diagrammatic sectional view of a purge gas generator usable in accordance with an aspect of the invention; here the precursor is composed into the desired radicals;

FIG. 3 is a diagrammatic sectional view of a chemical vapor deposition apparatus according to a second embodiment;

FIG. 4 is a diagrammatic view of a chemical vapor deposition apparatus of a third embodiment of the invention.

### DETAILED DESCRIPTION OF THE INVENTION

Metal Organic Chemical Vapor Deposition (MOCVD) is one of the preferred methodologies for the formation of thin films of semiconducting materials during the manufacture of solid state electronics devices. One of the more efficient and reliable vapor delivery systems employs a large stainless steel showerhead 5 which incorporates a myriad of microinjectors 12 to disperse organometallic and nonmetallic compounds in precise flow patterns. During use and over time, these injector orifices 12 and the surrounding superstructure gradually accumulate nonvolatile deposits which reduce both the efficiency and reliability of the vapor deposition process, and the showerhead assembly must be cleaned. Cleaning methods that are being considered in the state of the art include plasma discharge, laser ablation, and wet chemical cleaning. Plasma discharge cleaning methods involve either highly reactive gases and/or large power expenditure, and seem to be most effective at removing organic deposits; laser ablation cleaning methods may, due to locally high temperatures, change the physical dimensions of critical components in unpredictable ways. The lasers required for such applications also require high power expenditures. With both the plasma discharge and laser ablation methods, another consideration is that the surface of the stainless steel might, at the atomic level, be changed sufficiently so as to allow a greater rate of accumulation of deposits by creating local dislocations in the metal lattice (nano-corrosion). The known wet chemical cleaning method is time consuming, and involves disassembly and removal of the large, massive showerhead, treatment with potassium hydroxide solution or sodium hydroxide solution, and reassembly with alignment to critical tolerances. The invention proposes an alternative chemical cleaning method in which organic free radicals are generated in situ by photolysis and subsequently allowed to react with the deposits at temperatures substantially lower than either plasma discharge or laser ablation methods realize. The methodology is based in part on the ability of organic free radicals to react with metals and to form volatile organometallic products. The advantages of this approach are that the showerhead assembly would not require removal, the products generated from the reactions would be removable by inert gas purge and/or vacuum trapping. Power consumption for generating radicals is relatively low compared to plasma or laser methods, and thermal shock would be obviated.

Anticipated reactions between organic free radicals and/or hydrogen or hydrogen radicals with selected commercially-available Group III metals and Group V derivatives of these metals (shown for gallium as typical; similar reactions may be written for aluminum and indium) are given below in equations.

Ga₍ₛ₎+CH₃._{(g)}→(CH₃)₃Ga₍₈₎

GaN₍ₛ₎+ 3/2H2(g)→Ga₍ₛ₎+NH_{3(g)}

GaN₍ₛ₎+6CH₃._{(g)}→(CH₃)₃Ga_{(g)}+(CH₃)₃N_{(g)}

GaP₍ₛ₎+ 3/2H2(g)→Ga₍ₛ₎+PH_{3(g)}

GaP₍ₛ₎+6CH₃._{(g)}→(CH₃)₃Ga_{(g)}+(CH₃)₃P_{(g)}

GaAs₍ₛ₎+ 3/2H2(g)→Ga₍ₛ₎+AsH_{3(g)}

GaAs₍ₛ₎+6CH₃._{(g)}→(CH₃)₃Ga_{(g)}+(CH₃)₃As_{(g)}

GaSb₍ₛ₎+ 3/2H2(g)ΘGa₍ₛ₎+SbH_{3(g)}

GaSb₍ₛ₎+6CH₃._{(g)}→(CH₃)₃Ga_{(g)}+(CH₃)₃Sb_{(g)}

Ga₍ₛ₎+H._{(g)}→GaH_{3(g)}

GaN₍ₛ₎+6H._{(g)}→GaH_{3(g))}+NH_{3(g)}

GaP₍ₛ₎+6H._{(g)}→GaH_{3(g))}+PH_{3(g)}

GaAs₍ₛ₎+6H._{(g)}→GaH_{3(g))}+AsH_{3(g)}

GaSb₍ₛ₎+6H._{(g)}→GaH_{3(g))}+SbH_{3(g)}

The apparati described in the exemplary embodiments have a pot shaped reactor housing, which comprises a side wall, surrounding the reactor interior in the shape of a ring, and a horizontal base. The reactor housing can be closed by a cover. Feed lines 7, 8 open out in a hollow body 5, which is secured to the inner side of the cover and forms a gas inlet member 5 by means, which are not illustrated. Inside the cavity of the gas inlet member 5 there is a gas distribution plate 10, so that the process gas flowing out of the feed lines 7, 8 can flow in a uniform distribution into the process chamber 2 through the outlet openings 12, which are disposed in the form of a sieve and are associated with a base 11 of the gas inlet member 5. The surface, which is perforated by the outlet openings 12 of the above mentioned base of the gas inlet member 5 forms a gas inlet surface located opposite the substrate support surface of a susceptor 3 at a constant spacing from the ceiling of the process chamber 2, which is formed by the bottom plate of the gas inlet member 5.

The susceptor 3, which is a substrate holder, is made in particular from silicon carbide coated graphite. The substrate holder 3 can be driven in rotation by means, that are not shown but are disclosed in U.S. Pat. No. 7,524,532 B2. The bottom plate 11 of the gas inlet member 5 can be provided with not shown cooling channels to be kept at a temperature, which is about 80 to 120° C.

Below the susceptor 3 heating elements 23 are provided to heat the susceptor 3 using IR or RF to elevated temperatures of about 600° C. and higher. These are the temperatures, at which the substrates 4 can be brought into the process chamber 2 onto the susceptor 3. The temperatures during the growth process may be higher.

The process chamber 2 is surrounded by a gas outlet ring 6, which is connected with a gas discharge line 15 with a not shown vacuum pump to evacuate the process chamber 2 or to keep the total pressure inside the process chamber 2 at reduced pressures during the growth step.

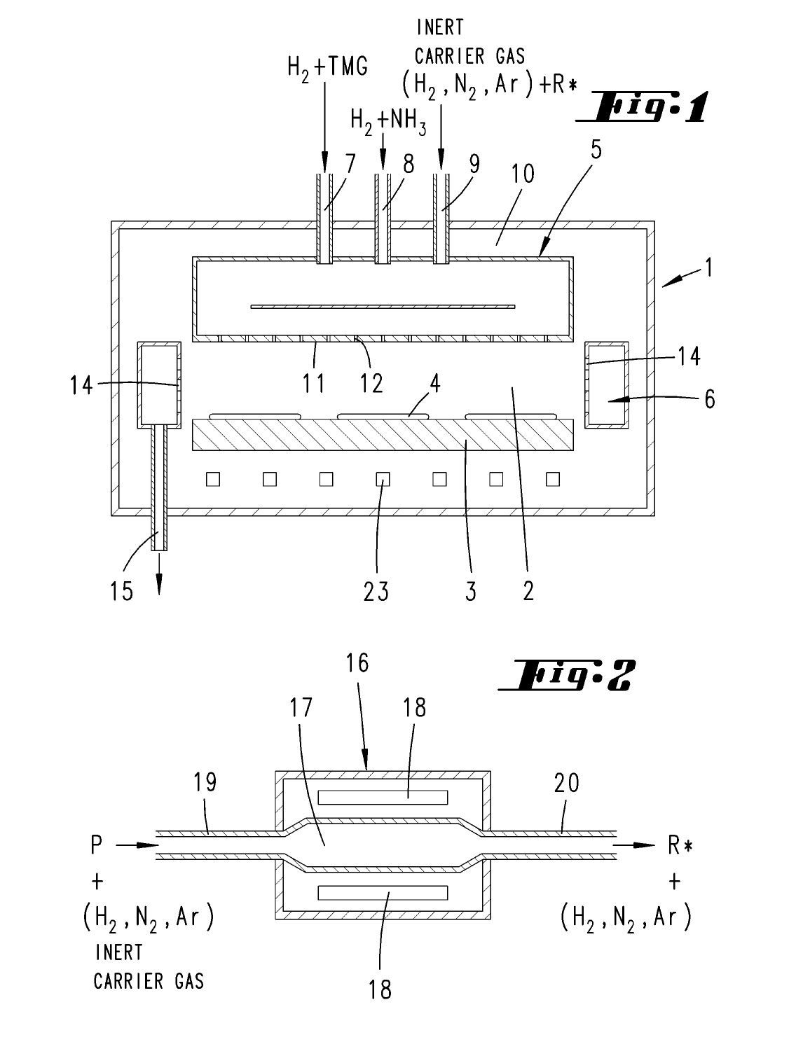

In the embodiment shown in FIG. 1 a purge gas inlet line 9 is provided, which opens into the cavity of the gas inlet member 5.

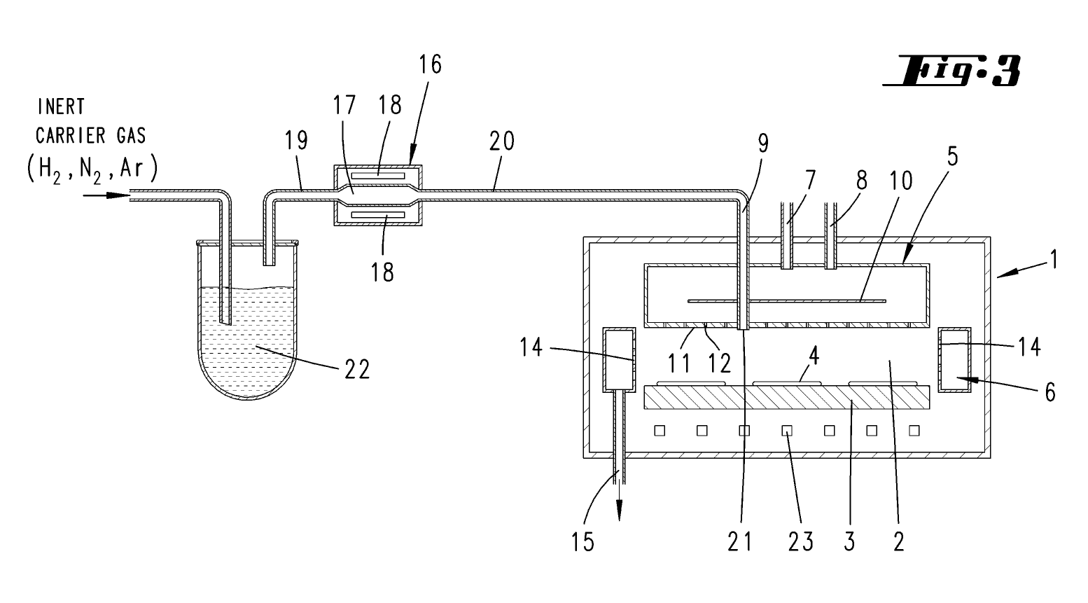

FIG. 2 shows a photochemical reactor 16, which serves as a purge gas generator. The photochemical reactor 16 has a gas outlet line 20, which is connected with the purge gas inlet line 9. The reaction chamber of the photochemical reactor 16 is fed with a gaseous precursor P and a carrier gas N₂, Ar or H₂ by a gas feed line 19. The reaction chamber is formed by a reaction tube 17 with elevated diameter wherein the tube wall is transparent to UV light. Wherein the UV required to initiate dissociation of the free radical from the precursor compound is dependent on the precursor itself. This UV light is produced by UV light sources 18. The UV light sources 18 provide light with a quantum energy high enough to dissociate bond groups in the precursor. Due to the breaking bonds the precursors dissociate into free radicals.

In one embodiment of the invention azomethane is used as a precursor and methyl radicals are produced by the following photochemistry:

CH₃N═NCH₃+hν→2CH₃*+N₂

In a second embodiment of the invention acetone is used as a precursor and dissociates into methyl radicals after the following photochemistry:

CH₃COCH₃+hν→2CH₃*+CO

In a third embodiment of the invention 2,3-butanedione is used as precursor, which reacts after the following equation into methyl radicals:

CH₃COCOCH₃+hν→2CH₃*+2CO

Byproducts include nitrogen or carbon monoxide, which do not disturb the etching process.

Potential halogenated radical precursors include CH₃Br, Br₂, BrCH₂CH₂BR,

CCl₃Br. Potential organic radical precursors are Pb(CH₃)₄, (CH₃)₂N₂,

(CH₃)₂Hg; CH₃NO₂, [(CH₃)₃C]₂O₂.

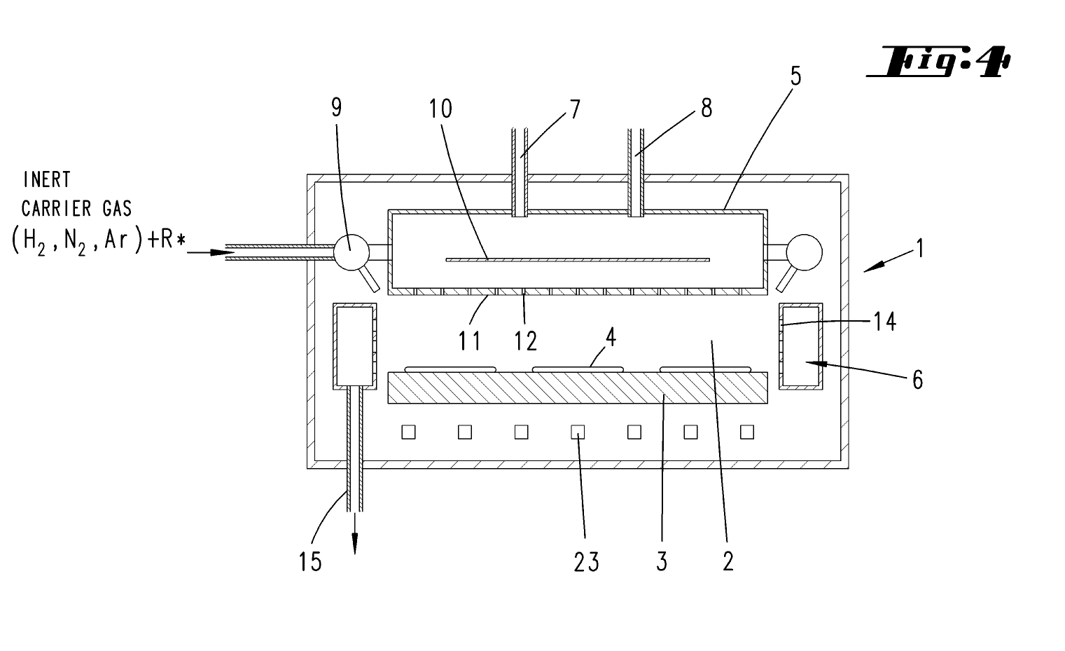

The embodiment shown in FIG. 3 has a photochemical reactor 16 as shown in FIG. 2. In addition a container 22 in form of a bubbler is shown containing a precursor, which is transported by a carrier gas to the photochemical reactor 16. In this embodiment the purge gas inlet line 9 opens directly into the process chamber 2. The opening 21 is located in the bottom plate 11 of the gas inlet member 5.

The embodiment shown in FIG. 4 has a different purge gas inlet apparatus 9 a ring shaped nozzle surrounds the gas inlet member 5.

The growth process takes place inside the process chamber 2. The process chamber 2 is a metalorganic chemical vapor deposition process (MOCVD). This is one of the preferred methodologies for the formation of thin films of semiconducting material during the manufacture of solid state electronic devices. The process gases, which are in particular TMG and NH₃, are mixed in a carrier gas in particular H₂ in a not shown gas supply system, which is connected to the stainless steel gas inlet member 5 by the pipes 7, 8. The process gases enter the process chamber 2 through the outlet openings 12 and decompose in the process chamber 2 and in particular on the surfaces of the substrates 4. A GaN-layer grows on the substrate. A multi layer structure can be grown on the substrates, which are preferred formed by sapphire (Al₂O₃).

During the process polycrystalline and/or amorphous deposition takes place on nearly all surfaces of the process chamber 2 not covered by substrates 4.

After the growth step the substrates 4 are removed out of the process chamber 2 and the reaction chamber is closed again. In an etching step the above mentioned free radicals R* are fed together with an inert carrier gas through the purge gas inlet line 9 into the process chamber 2. In the embodiment of FIG. 1 the free radicals enter the process chamber 2 through the outlet openings 12. In the embodiments of FIGS. 3 and 4 the free radicals R* enter the process chamber 2 directly. Inside the process chamber the free radicals R* react with the material which adheres to the surfaces and remove them by forming a volatile compound. This compound can be a metalorganic compound, which can be recycled to be used later as source material.

The etching process can proceed before the growth step but after putting substrates into the growth chamber. The surface of the substrates can be cleaned in that way. Contaminations are removed by a chemical reaction with the free radicals.

The method can also be applied in a GaAs-system, a InP-system, a GaInAsP-system with different substrate material where metalorganic components as TMGa, TMIn, TMAl and the TE(x) equivalents are used as precursors. The method can be applied in MOCVD systems including InP/GaS and ZnO systems. The above mentioned sapphire is not the only substrate. It is a preferred substrate, since substrates made from a II-VI or III-V material are possible as well.

In a further embodiment of the invention, the process is available on the MOCVD system, for example high temperature and low pressure.

The free radical process becomes useful in other tools, for example a cleaning furnace unrelated to the MOCVD system for cleaning MOCVD system or non-MOCVD system components. For example it is possible to etch with free radicals MOCVD reactor components after manufacturing or for example a shower head. Etching can take place inside the reactor itself or in a different reactor.

In a further embodiment of the invention, the free radicals are used to etch previously grown III-V layers from a substrate at defined areas. To define those areas the layer is provided with a mask. The mask has a material with is not affected by the free radicals. The masked substrate is put into a process chamber and exposed by a purge gas containing the above mentioned free radicals, which react with the layer material.

1. Method for depositing multicomponent semiconductor layers, in particular III-V epitaxial layers on at least one substrate (4), wherein process gases are introduced by means of a gas inlet member (5) into a process chamber (2), in which at least one substrate (4) is located on a susceptor (3), wherein in a deposition step at least one of said process gases decompose pyrolytically inside of the heated process chamber (2) into a first decomposition product, which forms together with a second decomposition product of a second process gas a layer on the surface of the heated substrate (4) and adheres to surfaces of the process chamber (2), wherein after or prior to the deposition step in an etching step the adherences are removed by introducing a purge gas containing a reactive substance into the process chamber (2), characterized in that the reactives substance is formed by free radicals.

2. Method for depositing multicomponent semiconductor layers in particular III-V epitaxial layers on at least one substrate (4), wherein process gases are introduced by means of a gas inlet member (5) into a process chamber (2), in which the at least one substrate (4) is located on a susceptor (3), wherein in a deposition step at least one of said process gases decompose pyrolytically inside of the heated process chamber (2) into a first decomposition product, which forms together with a second decomposition product of a second process gas a layer on the surface of the heated substrate (4), wherein a purge gas containing a reactive substance is introduced into the process chamber (2), characterized in that the reactive substance is formed by free radicals and the substrate is formed by a material, which is not affected by the free radicals, while being exposed to the purge gas prior to the growth of the layer.

3. Method for producing structurized III-V layers on a substrate comprising:
depositing a III-V-layer on a substrate in particular on a sapphire substrate;
masking the layer with a structured mask, which is not affected by a reactive substance;
removing not masked portion of the layer by emitting a purge gas containing said reactive substance to the masked layers,
characterized in that the reactive substances are free radicals.

4. Method according to claim 1, 2 or 3, wherein the free radicals are alkyl radicals.

5. Method according to claim 1, 2 or 3, wherein the precursor gas is azomethane, acetone or a different material, which is able to dissociate into a methyl radical or an ethyl radical.

6. Method according to one of claims 1 to 5, characterized in that a UV light with a wave length of about 280 nm or larger is used to photo-fragmentize a precursor to form said free radicals.

7. Method according to one of claims 1 to 6, characterized in that the reactive purge gas is introduced into the gas inlet member (5) through a purge gas inlet line (9).

8. Method according to one of claims 1 to 6, characterized in that the reactive purge gas is introduced separately from the gas inlet member (5) by a purge gas inlet line (9) into the process chamber (2).

9. Method for etching components of an MOCVD reactor or a wafer, wherein adherences from the surface of said components or from said wafer are removed by introducing a purge gas containing a reactive substance into the process chamber (2), characterized in that the reactive substance is formed by free radicals.

10. Device for depositing multicomponent semiconductor layers in particular III-V epitaxial layers comprising a process chamber (2), having a gas inlet member (5), a gas outlet member (6), a susceptor (3) for carrying at least one substrate (4) and a purge gas generator (16), wherein the gas inlet member (5) is connected by pipes (7, 8) with a gas supply system supplying the gas inlet member (5) with at least two process gases, wherein the purge gas generator (16) provides a purge gas containing a reactive substance to remove solid deposits from surfaces of the process chamber (2) or the substrate (4), characterized in that the purge gas generator (16) has a reaction chamber (17) and an energizer (18) emitting dissociation energy to a precursor in particular a precursor gas to dissociate free radicals from the precursor.

11. Device according to claim 10, characterized in that the gas inlet member (5) has the form of a shower head with a multiplicity of outlet openings (12) facing to the susceptor (3).

12. Device according to claim 10 or 11, characterized in that the purge gas generator (16) is a photochemical reactor, comprising a UV light source (18) and is connected via a gas outlet line (20) to a purge gas inlet line (9).

13. Device according to claim 10 or 11, characterized in that the energizer (18) is a heating device or a plasma generator.

14. Device according to one of claims 10 to 13, characterized by a cooled gas outlet surface of the gas inlet member (5), comprising outlet openings (12) facing to the susceptor (3), which is heated by a heater (23).

15. Device according to one of claims 10 to 14, characterized in a container (22) for a precursor gas, which is connected via a gas feed line (19) with the purge gas generator (16).
